(19) United States
(12) Patent Application Publication
(10) Pub. No.: US 2002/0188904 A1
(43) Pub. Date: Dec. 12, 2002

(54) Efficiency of fault simulation by logic backtracking

(75) Inventors: Xinghao Chen, Endwell, NY (US); Carolyn J. Asher, Endicott, NY (US); Thomas W. Bartenstein, Owego, NY (US); Thomas J. Snethen, Endwell, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 09/878,554

(22) Filed: Jun. 11, 2001

(51) Int. Cl. G06F 11/00; G01R 31/28

(52) U.S. Cl. 714/741

(57) ABSTRACT

A method for improving the efficiency of fault simulation using logic fault backtracing is described. With existing fault tracing methods, it is a common occurrence that too many faults are identified as potential faults to be processed by fault simulation. The method of the invention improves the fault-simulation efficiency by explicitly processing only those faults that are identified by logic fault tracing as potential faults. The present invention also reduces the storage usage with concurrent fault simulations. The inventive method includes: a) performing a fault-free circuit simulation on a circuit having at least one fault to be tested by fault simulation using one or plural tests, each of the tests including at least one input test vector; b) based on the fault-free circuit simulation, identifying which faults in the logic circuit are potentially tested by the test; c) performing the fault simulation on all remaining faults that were identified as potentially tested by the test; and d) repeating the previous steps for each of the tests.

### FIELD OF THE INVENTION

This invention is related to testing integrated logic circuits with or without memory, and more particularly to a method of reducing the number of faults to be considered when performing fault simulation for logic test and diagnosis.

### BACKGROUND OF THE INVENTION

In the last few decades there has been a drastic development in the field of microelectronics, particularly in the field of integrated circuits. Circuit density in the order of hundreds of millions of interconnected circuits has prompted the introduction of new techniques for automatically designing and testing the integrated circuits. In today's environment, and with the advent of VLSI (Very Large Scale Integration) and ULSI (Ultra Large Scale Integration), it is imperative more than ever that a chip to be manufactured be designed without any error. It is just as important that such chips be tested thoroughly to weed out any defective chip.

Although techniques for testing integrated circuits have evolved over the years, fault simulation remains the standard in test engineering. Fault simulation is important because it is used at many stages throughout the test engineering process and with most test methodologies For example, it is extensively utilized to grade the effectiveness of test sets by measuring the fault coverage achieved by these test sets. It is also applied for sorting test sequences of test data sets by measuring the effectiveness of individual test sequences. In addition, it is extensively employed in failure analysis and defect isolation (i.e., diagnostic fault simulation). Because of the extensive use of fault simulation throughout the test engineering process, it is advantageous to improve the computational efficiency of fault simulation techniques.

A conventional generalized circuit model is illustrated in FIG. 1, wherein components of a circuit (10) are divided into combinational logic blocks (15) such as AND, NAND, OR, NOR, XOR, XNOR gates, and memory blocks (20) such as latches, flip-flops, RAMs, ROMs, and the like. Depending on a specific test methodology, the memory blocks (20) in circuit (10) may be implemented having either a full-scan, partial-scan, or non-scan architecture. Full-scan or partial-scan designs configure at least some of the latches and flip-flops as shift registers into one or more scan chains. A scan load (shift-in) operation sets these registers to desired values, while a scan unload (shift-out) operation shifts out the contents of these registers for comparison with the expected results.

Still referring to FIG. 1, circuit (10) is provided with a plurality of input pins (PI0, . . . , PIn) and clock signal pins (CLK0, . . . , CLKp) as primary inputs, and a plurality of pins (PO0, . . . , POm) as primary outputs. Depending on the full-scan or partial-scan configurations, circuit (10) may also be provided with a plurality of scan-in inputs (SI0, . . . , SIk) and a number of scan-out outputs (SO0, . . . , SOq). When circuit (10) is configured for non-scan, then the scan-in inputs (SI0, . . . , SIk) and scan-out outputs (SO0, . . . , SOq) do not exist. With complex designs, a small number of the combinational (15) and memory (20) blocks may be used for clock distribution and gating to control other memory (20) blocks. When bi-directional bus structures are present, a subset of circuit (10) inputs (PI0, . . . , PIn) and outputs (PO0, . . . , POm) may share bi-directional pins which can be either 2-state or 3-state. Depending on design and test methodologies, SI and SO signals may or may not exist in a particular circuit. Clock signals CLK0, . . . , CLKp feed the combinational logic gate (15) to reflect circuits with gated clocks. For circuits without clock gating logic, CLK0 . . . , CLKp directly feed the memory gate (20)

Fault Simulation

Fault simulation is a process of applying test data to the inputs of a circuit and propagating the signal values to measure points (PO0, . . . , POm, and to measurable scan latches). When propagating the signal values, fault models are used to mirror the behavior of potential defects, and faulty signal values are propagated toward measurable points as well. A fault is logged as tested when the presence of the fault causes at least one of the measure points to change its fault-free signal values to an opposite value (i.e., either from logic ‘1’ to ‘0’ or vice versa). Traditionally, 1/0 and 0/1 (for value-in-fault-free-circuit/value-in-faulty-circuit) are used to denote a fault effect carried on a (digital) signal.

Most conventional gate-level fault simulators use a single-fault model, which assumes that only one fault appears in the circuit. Consequently, faults are processed independently from each other during fault simulation using a single-fault model. Since any number of multiple fault effects caused by different defects can exist in a circuit, the single-fault model is an abstraction to simplify the fault simulation complexity. Fault simulation using a multiple-fault model assumes that more than one fault exists in a circuit and propagates the multiple fault effects accordingly at the same time. Since there exist a large number of multiple-fault combinations, it is not practical in most fault simulation scenarios to simulate a test set with all possible combinations of multiple faults. Therefore, a fault simulation with multiple-fault models is used only selectively, with a small number of possible multiple-fault combinations.

FIG. 2 shows an example of a conventional logic circuit along with faults using the standard stuck-at fault model. Both stuck-at-0 and stuck-at-0 faults are considered at each pin of a gate. A prior art technique named ‘fault collapsing’ reduces faults to be processed by fault simulation by identifying faults which are guaranteed to be tested when associated representative faults are tested and are guaranteed not to be tested when the associated representative faults are not tested. Faults represented by these representative faults are not explicitly processed by fault simulation. For example, any input pattern that tests a stuck-at-0 fault at the output pin of an AND gate also tests the stuck-at-0 faults at the AND gate input pins. Therefore, there is no need to explicitly process the stuck-at-0 input pin faults during fault simulation. Therefore, only collapsed stuck-at faults are shown in FIG. 2. Fault collapsing is not performed for the stuck-at faults at the circuit input and output pins due to other test engineering concerns.

Fault simulation techniques typically use either concurrent-fault (CF) simulation, single-pattern multiple-fault (SPMF) simulation, or parallel-pattern single-fault (PPSF) simulation. SPMF simulation is also known as single-pattern parallel-fault (SPPF) simulation, and PPSF as multiple-pattern single-fault (MPSF) simulation. Although various improvements have recently been introduced to identify non-active faults associated with each input pattern, CF simulation conceptually processes the effect of all the faults concurrently for each input pattern. Due to the nature of this fault-processing concurrence, CF simulation uses the largest amount of storage during fault simulation. In contradistinction, SPMF and/or SPPF simulation processes at a time one input pattern with multiple faults. Furthermore, most SPMF/SPPF simulations process one input pattern and either 31 (63) or 32 (64) faults at a time to take advantage of the 32-bit (64-bit) word-length of a typical computer hardware architecture. Methods that process 31 (63) faults at a time combine the fault-free circuit simulation with the 31 (63) faulty circuits simulations, while methods that process 32 (64) faults at a time process the fault-free circuit simulation first and then process the 32 (64) fault circuit simulations next. Conversely, PPSF/MPSF processes multiple input patterns and a single fault concurrently. Depending on the implementation, PPSF/PSF simulations process either 31 (63) or 32 (64) input patterns in parallel to take advantages of the 32-bit (64-bit) computer hardware architecture.

FIG. 3 illustrates an example of a prior art fault simulation with the selected fault being stuck-at-0 on the upper input leg of gate g1. After applying the input pattern (input_pattern=(in1=1, in2=0, in3=1, in4=1, in5=0)) to the circuit shown, signal values are propagated towards the outputs (Note: simulation values of the signals are shown in parentheses along with the fault effects). Comparison of the simulation values of the fault-free and faulty circuits reveals the fault effect of 1/0 at output out1, which means that the indicated stuck-at fault is tested by the input pattern. FIG. 4 shows all the tested stuck-at faults by this input pattern.

Fault simulation is also useful as a process to identify potential causes for circuits which do not behave as modeled. In this case, a simulated test pattern contains the expected output values at the measurable points of the circuit (either outputs or scannable latches). However, either through simulation of a different model, or through application of the test patterns at a tester, different results than the expected values were obtained. These differences are called failures. Fault simulation is used to determine which of the modeled faults most closely matches the failures. The knowledge of which modeled fault best matches the miscompares is used to identify and correct the cause of the failure.

There is a large savings potential in reducing the number of faults that have to be processed by diagnostic fault simulation. When fault simulators are used to collect fault coverage statistics, faults need no longer be simulated after the first time they are tested. Since diagnostic fault simulation depends on knowing every time that a fault is tested, then in a diagnostic mode, every fault must be simulated for every pattern. Hence, the performance of diagnostic fault simulation is directly proportional to the number of faults simulated.

Fault Tracing

Fault tracing is a process of determining potential faults when fault effects are either observed or assumed to be observed after applying a test to the circuit. Identified potential faults are then processed by fault simulation.

Typical prior-art fault tracing is performed by way of topological and structural tracing through the circuit. It begins with circuit observation/measure points (typically, primary outputs and measurable scan latches) where fault effects are observed after a test is applied and traces the paths back to its controllable points (typically, primary inputs and controllable scan latches). Faults on these traced paths are potential fault sources which may be responsible for causing the observed fault effects at the measure points.

FIG. 5 illustrates an example of prior-art fault tracing, assuming that an input pattern of {in1=1, in2=0, in3=1, in4=1, in5=0} is applied and out1=1/0 is observed at the tester. A logic backtrace is performed starting at the failing output(s), and all faults within that backtrace are subjected to further analysis (fault simulation). A total of 18 potential faults are identified by topological fault tracing. These 18 faults are then processed by fault simulations. This example will be utilized hereinafter when describing fault tracing of the present invention.

Among the many issues associated with fault simulation, computation efficiency and storage usage are two of the most critical concerns. The present invention reduces the number of faults to be processed by fault simulation. This results in a reduced number of fault simulation passes with PPSF/MPSF/SPSF simulation methods, lower fault simulation time, and reduced storage usage with CF simulation methods. With large circuits, prior-art topological and/or structural fault tracing methods may still result in large numbers of potential faults and consequently require a considerable amount of fault simulation effort.

In contradistinction, prior art methods have attempted to improve the efficiency of fault simulation by replacing fault simulation by a backtracing process based upon a good-circuit simulation. To avoid erroneously marking off faults as tested, such methods have tended to be pessimistic; that is, they sort faults into two groups: faults that are definitely tested, and faults that are not definitely tested. The faults which are not definitely tested are then either regarded as untested, or subjected to fault simulation.

Another class of prior art methods make no attempt at identifying tested faults, but instead sort faults into two groups, consisting of one group that are definitely not tested, and faults that may be tested. The faults which are definitely not tested need be considered no longer, and faults which may be tested are subjected to fault simulation. These prior art methods perform backtracing purely from the structure of the circuit and do not take any good-circuit simulation values into account.

The backtracing method in the second-mentioned class prior art method identifies faults that cannot possibly account for an observed failure because there is no logical connection between the site of the assumed fault and the observation site. Whereas the second-mentioned class of prior art backtracing methods are applicable to diagnostic simulation, where a subset of the observation points have been recorded as failing under application of the test, they are not applicable to the classical before-the-fact simulation, because in the latter case, all observable nodes would have to be considered, and all the original faults would be included in the backtracing, resulting in no improvement on the number of faults to be processed.

Related patents and publications to the present invention are:

U.S. Pat. No. 3,961,250 to Snethen describes a fault-simulation-based test generation method. It first applies a test pattern to the primary inputs and propagates the pattern through a logic network. A particular logic gate within the network is then selected and a specific fault associated with the particular logic gate is assumed. A test value for this assumed specific fault in the simulated network is then propagated towards a primary output one logic stage at a time, by backtracing through the network to a primary input to determine which primary input value must be altered in order to propagate the assumed fault towards the primary outputs.

U.S. Pat. No. 4,996,659 to Yamaguchi et al describes a method of using contact-less probing devices to monitor the inputs and outputs of a functional gate in a circuit. The observable values at the primary outputs are then compared with the simulated results based on the normal functional operation of the block.

U.S. Pat. No. 4,423,508 to Shiozaki et al describes a logic tracing method to obtain a history of the hardware status concerning a detected error (with the hardware). Circuits including a memory continuously write the hardware status information at constant time intervals, and a control unit determines when to start and stop recording the hardware history. The recorded hardware information is inspected during diagnosis when an error is detected. A description on how the recorded hardware information are used is not provided.

U.S. Pat. No. 6,105,156 to Yamaguchi describes an LSI tester for use in a fault analysis to facilitate locating possible defects in an LSI circuit. A path analysis method is described as backtracing a predetermined number of connections along a designated signal flow path from one of the flip-flops where an error is detected based on circuit information of the LSI circuit, and identifying the flip-flops (or external terminals) in the designated signal flow path which are the flip-flops (or external terminals) first reached from the error detection point as an arrival point.

Numerous publications on fault simulation methods are available in the art. Many of these publications are summarized in Chapter 5 of the book “Digital Systems Testing and Testable Design” by Miron Abramovici et al. (1990, W. H. Freeman and Company, and later IEEE Press) and Chapter 5 of a book “Essentials of Electronic Testing for Digital, Memory & Mixed-Signal VLSI Circuits” by Michael B. Bushnell et al. (2000, Kluwer Academic Publishers).

Articles “Critical Path Tracing” by Miron Abramovici et al (IEEE Design and Test of Computers, vol. 1, no. 1, pp 83-93, February 1984) and “Critical Path Tracing in Sequential Circuits” by P. R. Menon et al. (IEEE Proceedings of International Conference on Computer-Aided Design, pp 162-165, 1988) described an alternative method to fault simulation through approximation. However, this approximation method is detrimental to other main applications of fault simulation such as diagnosis and test generation. The Critical Path Tracing method determines which faults are tested based on fault-free circuit simulations. Once an input vector is simulated in the fault-free circuit, the method starts by tracing back from the outputs to the inputs. Along the way, it marks off faults considered to be tested. An approximation is made when the tracing encounters reconvergent circuit structures. The method takes a pessimistic approach in marking off tested faults whose observation relies on the propagation through reconvergent circuit structures.

### OBJECTS OF THE INVENTION

Accordingly, it is a primary object of the present invention to provide a method for reducing the number of faults to be processed by fault simulation.

Another object of the present invention is to reduce the storage used by concurrent fault simulation by reducing the number of faults to be processed with each test input.

Still another object of the present invention is to improve fault simulation efficiency by explicitly simulating a smaller number of faults.

### SUMMARY OF THE INVENTION

In a first aspect of the present invention, the number of faults to be processed by fault simulation are significantly reduced when test inputs, internal circuit node states, good machine (i.e., fault-free-circuit) simulation values, and observed fault effects at measurable points (i.e., primary outputs and measurable scan latches when a scan unload is used in the tests) are known. The invention takes into account the good machine simulation and eliminates from consideration any faults for which there is no structural connection to the observation points, but for which all such connections are blocked by the good-circuit signal state. In this manner, by taking into account the good-circuit simulation state, it is able to further reduce the number of faults requiring fault simulation for diagnostics. Furthermore, it is also applicable to the “before-the-fact” simulation, where the effect of the good-circuit simulation is used to limit the backtracing and reduce the number of faults that must be processed by fault simulation.

In another aspect of the invention, there is provided a method of logic fault tracing that includes the steps of: a) applying a test to the inputs of the circuit; b) performing a good-machine simulation of the circuit to obtain the value (state) of each internal node; c) identifying potential faults by starting logic fault tracing at measure points with observed fault effects; d) tracing through circuit blocks from outputs to sensitized inputs until directly controllable points such as primary inputs and controllable scan latches are reached; and e) marking faults on the traced paths as potential faults.

In still another aspect of the invention, when used for fault simulation, the invention categorizes faults into two sets—definitely untested faults and potentially tested faults—in contradistinction to prior art methods (e.g., the Critical Path Tracing method) which identify definitely tested faults and potentially untested faults. The resulting fault partitions for circuits with reconvergent structures/topologies therefore differ from prior art methods.

### BRIEF DESCRIPTION OF THE DRAWINGS

The accompanying drawings, which are incorporated herein, and which constitute a part of the specification, illustrate presently an embodiment of the invention and, together with the general description given above and a detailed description of the preferred embodiment given below, serve to explain the principles of the present invention.

FIG. 1 is a schematic diagram of a prior-art logic circuit model.

FIG. 2 shows an example of a typical combinational logic circuit with stuck-at faults to be processed by fault simulation.

FIG. 3 illustrates a prior art fault simulation with the input pattern and a tested stuck-at fault.

FIG. 4 shows all stuck-at faults tested by an input pattern, applicable to the example shown in FIG. 3.

FIG. 5 is an example of potential faults identified using prior-art fault tracing methods.

FIG. 6 shows fewer potential faults identified using logic fault tracing according to the present invention, compared with the faults identified using prior-art methods, utilizing for this purpose the example shown in FIG. 5.

FIG. 7 shows the logic fault tracing through AND and NAND blocks.

FIG. 8 shows logic fault tracing through OR and NOR blocks.

FIG. 9 shows logic fault tracing through multi-port latches.

FIG. 10 shows logic fault tracing through MUX blocks.

FIG. 11 shows logic fault tracing through XOR blocks.

FIG. 12 shows logic fault tracing through XNOR blocks.

FIG. 13 shows logic fault tracing through three-state bus drivers.

FIG. 14 shows logic fault tracing through a random-access memory (RAM).

FIG. 15 shows logic fault tracing through a read-only memory (ROM).

FIG. 16 shows a flow chart describing the logic fault tracing, according to the present invention.

FIG. 17 shows a typical fault simulation flow using the present invention of logic fault tracing which is performed at Steps C and D.

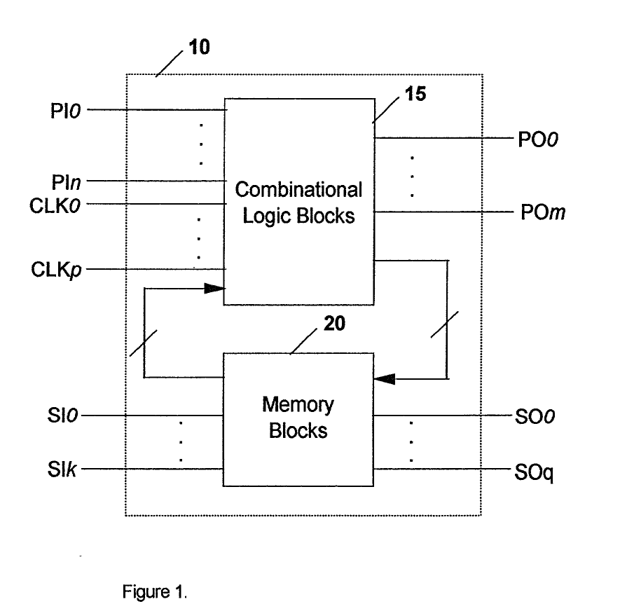

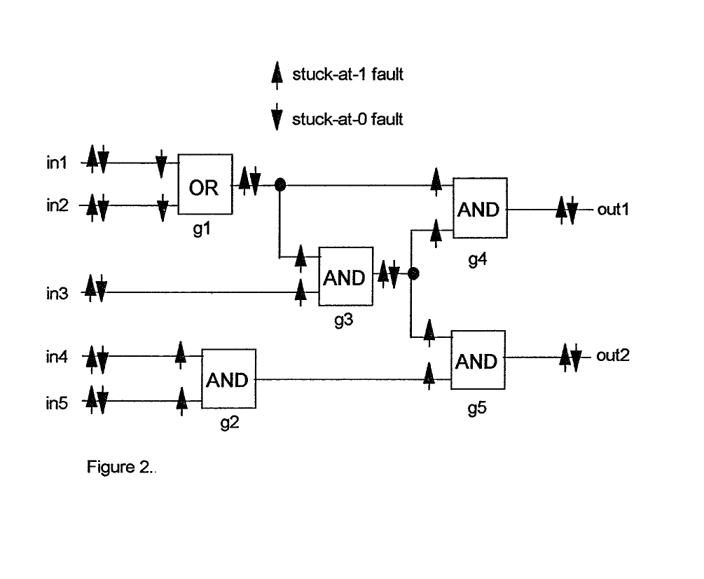

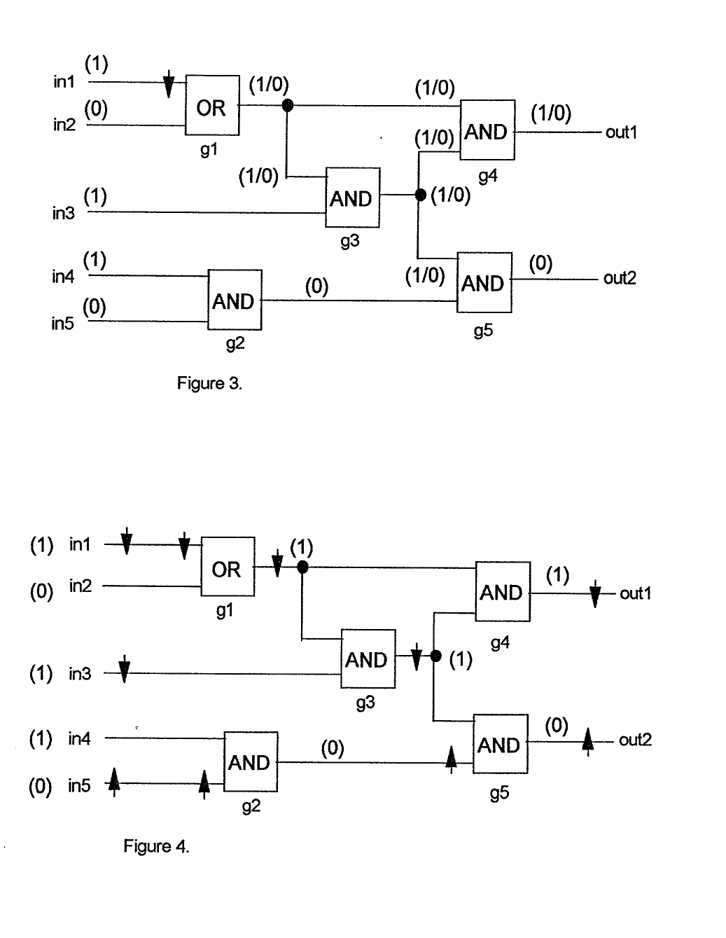

### DETAILED DESCRIPTION OF A PREFERRED EMBODIMENT OF THE INVENTION

A preferred embodiment will be explained hereinafter focusing on the reduced number of faults to be processed by fault simulation. Practitioners of the art will readily recognize that the first stated object of the invention is achieved in a like manner without the benefit of the observed fault effects by assigning a failure to each measurable point.

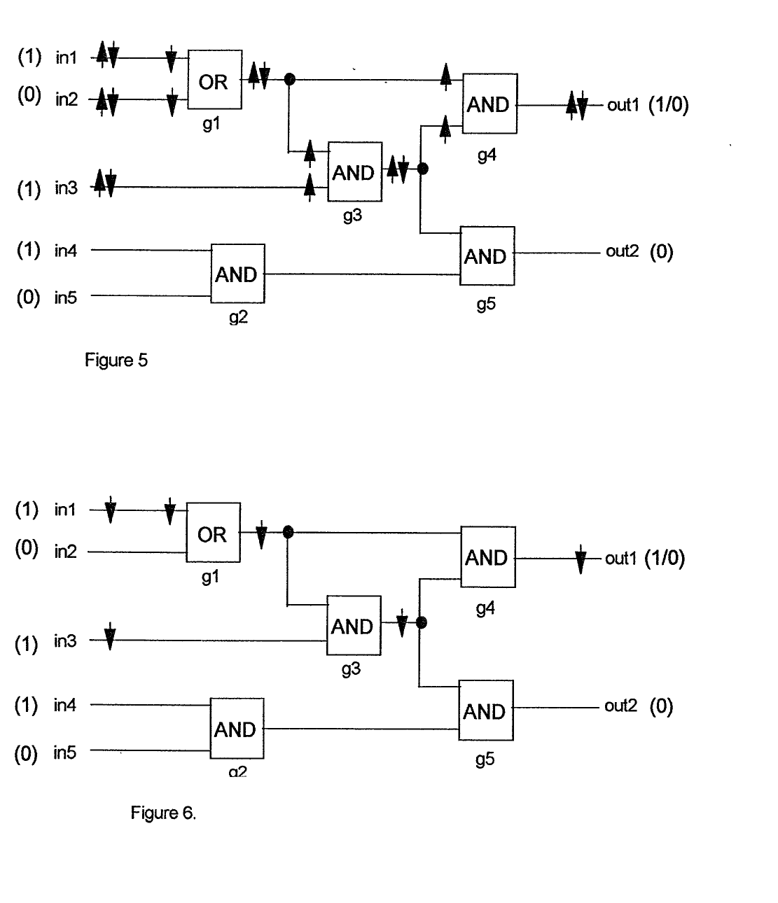

As previously stated in the Background of the Invention, FIG. 6 illustrates an example of six potential faults identified to be processed by fault simulation when using the same circuit and test inputs illustrated in the previous figure. When applying prior-art fault tracing to the circuit of FIG. 5, a total of 18 faults were required to be processed by fault simulation. The present invention identifies 6 faults to be potentially responsible for producing the observed fault effect 1/0 at out 1, thus, eliminating a total of 12 faults to be processed, a reduction of 66%. This reduction is accomplished by tracing backwards through the logic, beginning at observation nodes at which failures are observed (or assumed to be observed). At each gate of the logic, backtracing determines which faults have the potential of causing the effect of the observed (or assumed) failure based on the nature of the gate and the state of the circuit. The present embodiment describes the rules that determine the potential faults for various types of gates. These types of primitives are sufficient to model very complex integrated circuits.

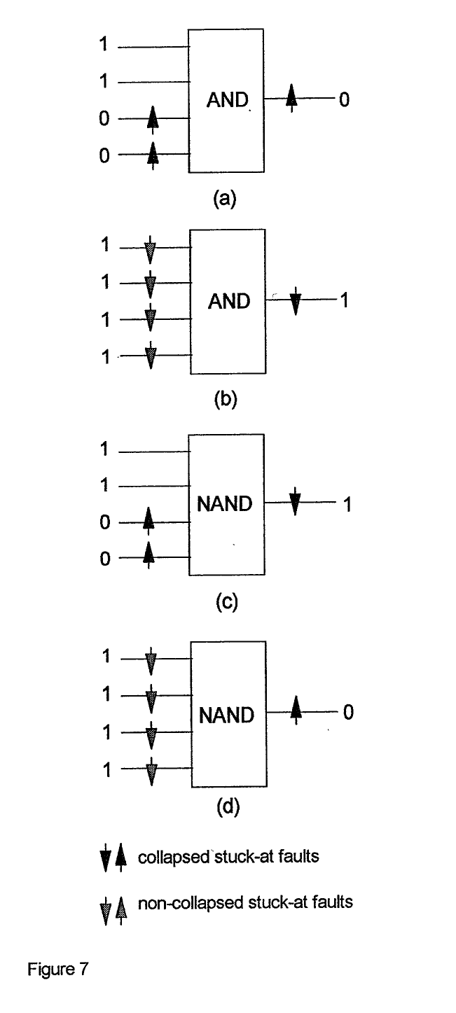

Referring to FIG. 7, an AND/NAND gate is shown having several inputs and one output. In the case of a AND/NAND gate, all inputs are backtraced when the inputs are at the non-controlling value (logic 1). When the inputs are set to their controlling value (logic 0), then only those inputs are backtraced. More specifically, in FIGS. 7(a) and (c), when the output ‘stuck-at’ fault is identified as potentially tested, the indicated input ‘stuck-at’ faults are likewise identified as potentially tested, and the associated input paths are backtraced. In FIGS. 7(b) and (d), when the output ‘stuck-at’ fault is identified as potentially tested, the indicated input ‘stuck-at’ faults are identified as potentially tested and all the input paths are backtraced.

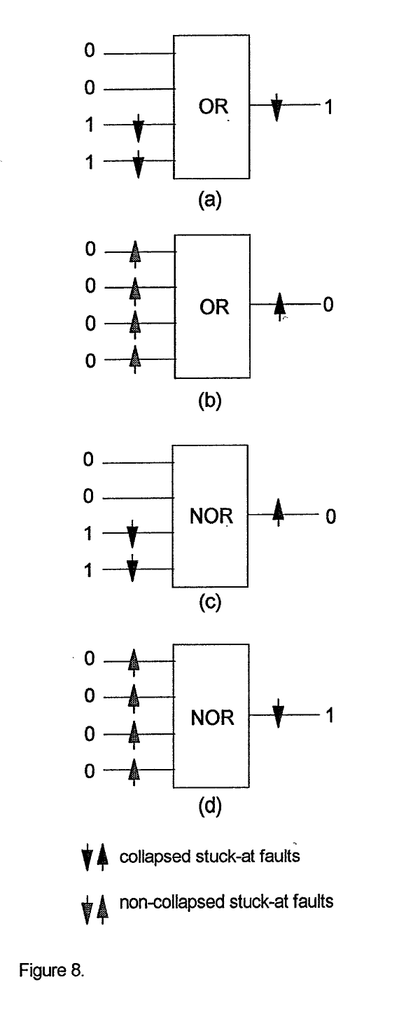

Referring now to FIG. 8, an OR/NOR gate is shown having several inputs and one output. When all the inputs of the OR/NOR gate are at their non-controlling value (logic 0), all the inputs are backtraced. If some inputs are at their controlling value (logic 1), then only those inputs are backtraced. More specifically, in FIGS. 8(a) and (c), when the output stuck-at fault is identified as potentially tested, the indicated input stuck-at faults are likewise identified as potentially tested, and the associated input paths are backtraced. In FIGS. 8(b) and (d), when the output stuck-at fault is identified as potentially tested, the indicated input stuck-at faults are identified as potentially tested and all the input paths are backtraced.

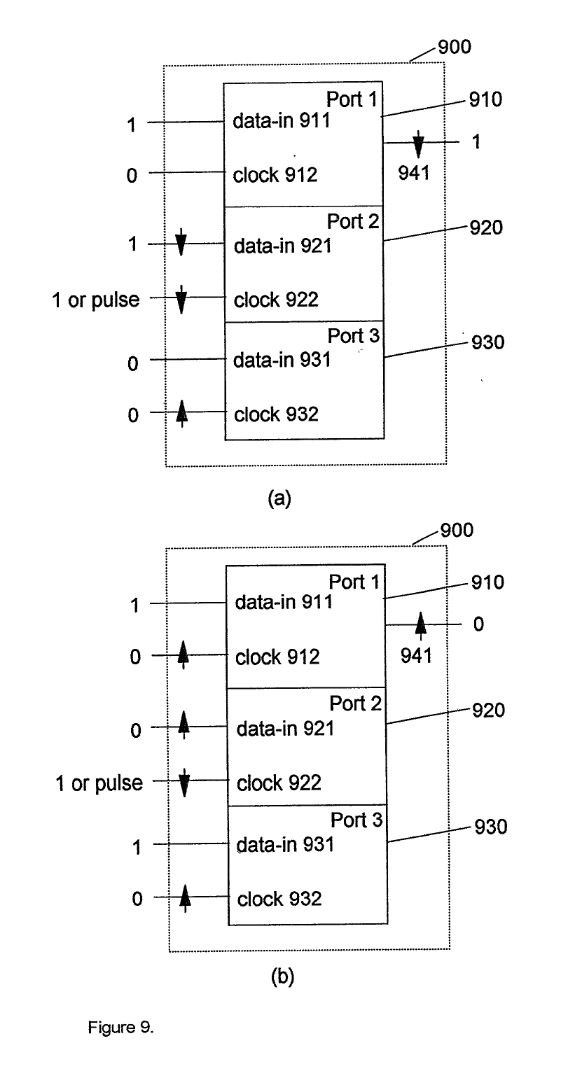

Referring now to FIG. 9, latch (900) stores a single bit of information, and is level-sensitive with respect to clock inputs (912, 922, 932). When clock input (922) to one port (920) is “on” (logic 1), and the clock inputs to the remaining ports (910 and 930) are “off” (logic 0), the content of the latch is the value on the data input (921) associated with the clock that is “on”. When the clock turns “off”, the data is said to be “stored” in the latch. When all the clocks are “off” the latch content remains constant, unresponsive to signal changes on the data inputs. When the clock inputs to two or more ports are “on” simultaneously, the latch content is unpredictable (logic “X”). While FIG. 9 shows a latch having three ports, it is understood that a latch may have any number of ports. The value at the latch output (941) equals the content of the latch at all times. The clock input for an input port is backtraced if either: (1) the clock remains at 0 throughout the pattern and its associated data input value is opposite of the latch output value, or (2) the clock is at 1 or was pulsing during the pattern and its associated data input value is the same as the output value of the latch. The data input of the latch is backtraced if its value is the same as the latch output value and its associated clock input is at 1 or is pulsing during the pattern.

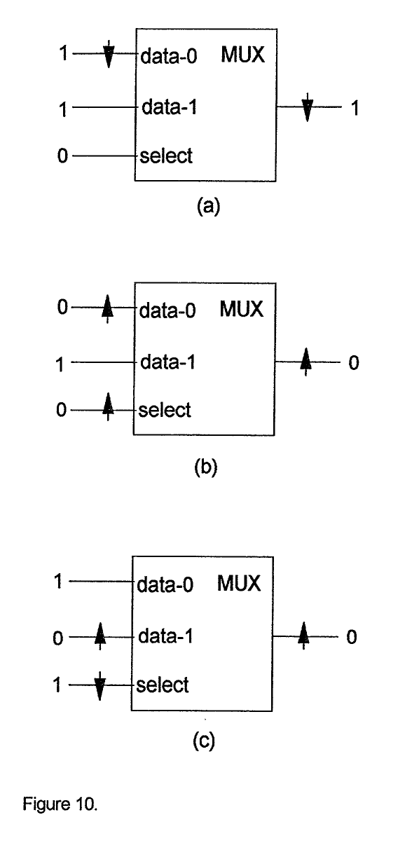

Referring to FIG. 10, a MUX is shown having two data and one select inputs, and one output. The MUX operates such that when the select input is set to 0, the output is the value on the data-0 input. When the select input is set to 1, the output is the value on the data-1 input. The select line is backtraced if the data inputs are at opposite values and the stuck-at fault at the output is identified as potentially tested. The selected data input is also backtraced, as determined by the value on the select input. FIGS. 10(a), (b) and (c) illustrate the logic backtrace rule applied by the present invention to the MUX.

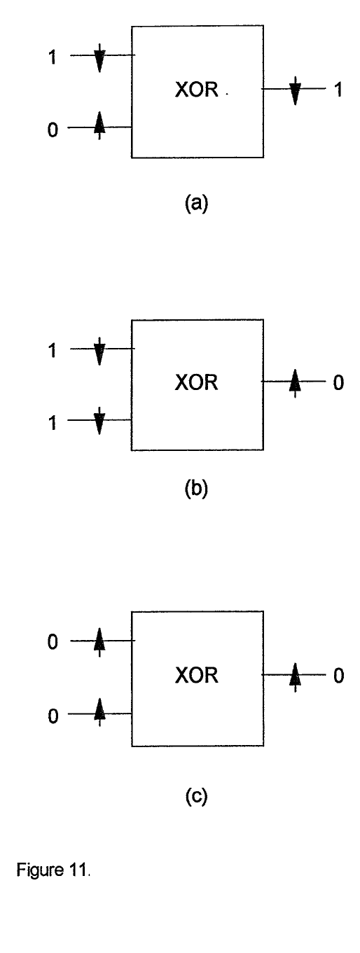

Referring to FIG. 11, there is shown an XOR gate having two inputs and one output. When the output stuck-at fault is identified as potentially tested, the input stuck-at faults are also identified as potentially tested and the input paths are backtraced. The XOR gate logic backtrace rule applied by the present invention is illustrated in FIGS. 11(a), (b) and (c).

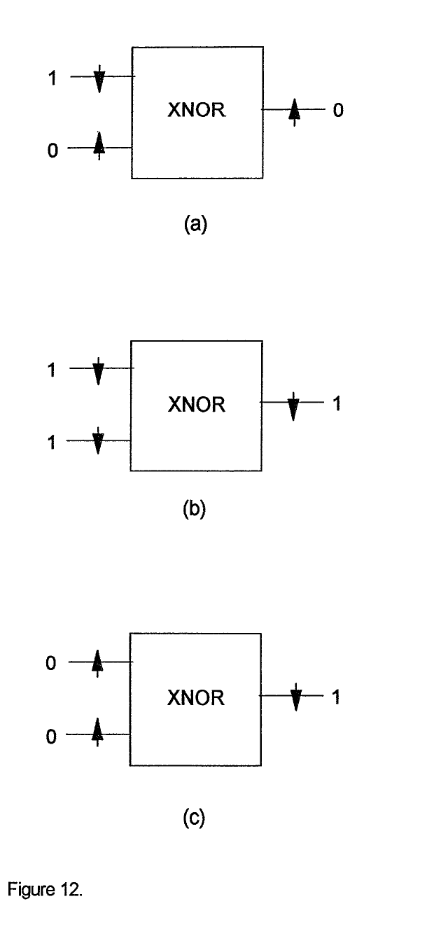

Referring to FIG. 12, there is shown an XNOR gate having two inputs and one output. When the output stuck-at fault is identified as potentially tested, the indicated input stuck-at faults are also identified as potentially tested and the input paths are backtraced. The XNOR gate logic backtrace rule applied by the present invention is illustrated in FIGS. 12(a), (b) and (c).

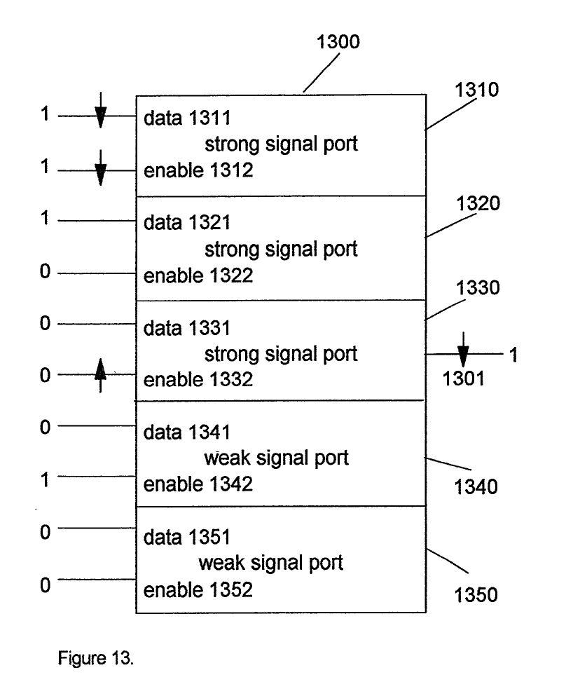

Referring to FIG. 13, a three-state bus driver provided with several ‘strong signal ports’ and ‘weak signal ports’ is shown (1300). When at least one strong signal port (such as port 1310) is enabled, the bus state is determined by the enabled inputs of the strong signal ports (1311 and 1312). When all strong signal ports are disabled and at least one weak signal port is enabled, the bus state is determined by the inputs to the enabled weak signal ports. We represent the value of the bus driver output (1301) by V, which is 1 in FIG. 13. The strong ports are examined first when backtracing through a three-state bus. If any strong port (such as 1310) is enabled, the data input (1311) for that port is backtraced and the data input net is tagged to indicate that any stuck-at-^{˜}V and corresponding faults encountered during backtracing the net are potentially tested by the test. If any strong port (such as 1310) is enabled and there is at least one weak signal port (such as 1340) which is also enabled with the data input value of ^{˜}V (i.e., opposite of the bus state), the strong port enable input (1312) is backtraced and the enable input is tagged to indicate that any stuck-at-0 (stuck-at “disable”) fault associated with the net and corresponding faults encountered during backtracing the net are potentially tested by the test. If no strong port is enabled, and any strong port data input is ^{˜}V, the port enable input is backtraced and the enable input net is tagged to indicate that any stuck-at-1 (stuck-at “enable”) fault associated with the net and corresponding faults encountered during backtracing the net are potentially tested by the test. If no strong port is enabled, the data input of each enabled weak port is backtraced, and the data input net is tagged to indicate that any stuck-at-^{˜}V and corresponding faults encountered in backtracing the net are potentially tested by the test.

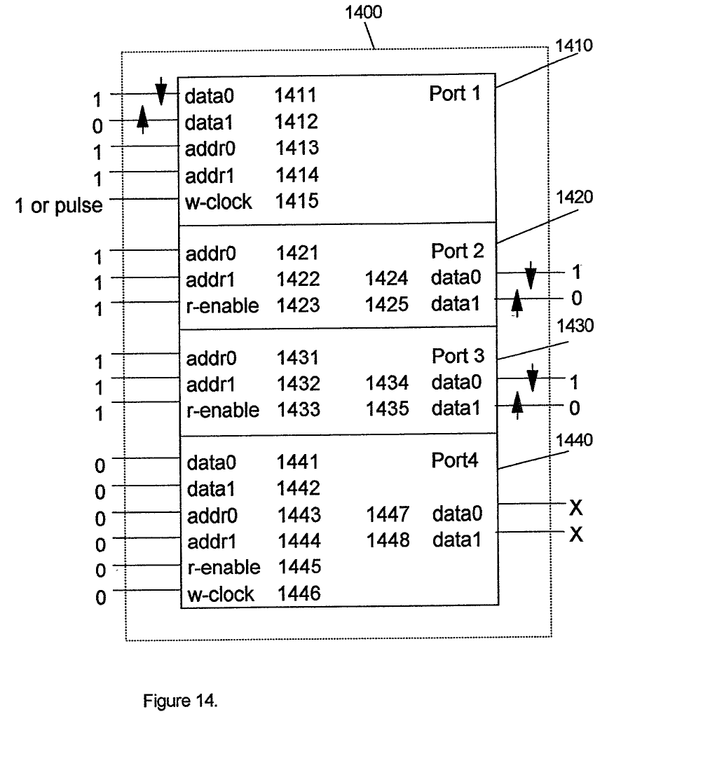

Referring to FIG. 14, RAM (1400) is modeled as a single gate with multiple ports (1410, 1420, 1430, and 1440). Port 1 (1410) is a write port having data inputs (1411 and 1412), address inputs (1413 and 1414), and a write-clock input (1415). When the write-clock input (1415) receives a positive-going pulse, the values on the corresponding data inputs (1411 and 1412) are written into the RAM address indicated by the corresponding address inputs (1413 and 1414). Port 2 (1420) is a read port having address inputs (1421 and 1422), a read-enable input (1423), and data outputs (1424 and 1425). When the read-enable input (1423) is at 1, the RAM content at the address indicated by the corresponding address inputs (1421 and 1422) is set on the corresponding data outputs (1424 and 1425). When the read-enable input (1423) is at 0, the corresponding data outputs (1424 and 1425) are set to READOFF. The READOFF value is determined by a parameter on the RAM which may be either 0, 1, high-impedance (“Z”), or indeterminate (“X”). Port 3 (1430) is a read port, and operates in the same manner as read port 2 (1420). Port 4 is a read-write port, having data inputs (1441 and 1442), address inputs (1443 and 1444), a read-enable input (1445), a write-clock input (1446), and data outputs (1447 and 1448). It operates in the same manner as the read port and the write port, combining the functions of the two port types into a single port. When the write-clock input (1446) receives a positive-going pulse, the values on the corresponding data inputs (1441 and 1442) are written into the RAM address indicated by the corresponding address inputs (1443 and 1444). When the read-enable input (1445) is at 1, the RAM contents at the address indicated by the corresponding address inputs (1443 and 1444) are set on the corresponding data outputs (1447 and 1448). When the read-enable input (1445) is at 0, the corresponding data outputs (1447 and 1448) are set to READOFF. Each RAM must have at least one read-write port, or lacking a read-write port, it must have at least one read port and at least one write port. Provided that the minimum requirement is met to assure means of both writing and reading the RAM, the RAM may have any number of ports in any combination of the above-described port types. In the example of FIG. 14, there are two address inputs per port, indicating that the RAM contains four storage addresses, each containing two bits, corresponding to the number of data bits per port. Generally, the RAM may have m storage locations (words) and n bits per word, in which case there are M=log2(m) address inputs and n data-inputs and/or data-output pins per port.

Still referring to FIG. 14, when a random access memory (RAM) is encountered during backtracing, processing must occur for the port whose data output was backtraced into, and for all write and read-write ports. The notation data-in(i,j), addr(k,j), write-clock(j), read-enable(j), and data-out(i,j) refers to pins and their associated nets, wherein i is the data bit position (0≦i<n); j is the port number; k is the address bit position (0≦k<M); n is the number of bits per word; M is the number of address inputs per port; and m=2^{M}, the number of words in the RAM. The backtraced-into data output is referred to as data-out(b,p), the backtraced-into port is port p, and the data bit position is b. The value on the data-out(p,b) is represented by V, where V may be either 1, 0, or Z (high impedance).

If read-enable(p) is at 1 (enabling), and V is different from READOFF (the value on the RAM outputs when disabled), then the read-enable(p) input is backtraced and the read-enable(p) input is tagged to indicate that any stuck-at-0 (stuck-at “disable”) fault associated with the net and corresponding faults encountered during backtracing the net are potentially tested by the test. If read-enable(p) is at 1 (enabling), then the content of the RAM is searched. If V is stored in position b at address A=(A₀, A₁, . . . A_{M-1}), then each address input addr(j,p) whose value is the complement of Aⱼ is backtraced, and the address input is tagged to indicate that any stuck-at-Aⱼ. fault associated with the net and corresponding faults encountered during backtracing the net are potentially tested by the test. Both the search and the identification of address inputs on which to continue backtracing stop when all the address inputs of port p have been identified, or when the entire address space has been exhausted, whichever happens first. When read-enable(p) is at 1, for each port j (i.e., which is either a write port or a read-write port), if the write-clock(j) is not pulsed, the write-clock(j) input is backtraced and the write clock input is tagged to indicate that any stuck-at-1 (write clock stuck “on”) fault associated with the net and corresponding faults encountered during backtracing the net are potentially tested by the test. If the write-clock(j) is pulsed, then proceed as follows:

Backtrace from data-in(b,j) and tag the input to indicate that any stuck-at-V fault associated with the net and corresponding faults encountered in backtracing the net are potentially tested by the test;

Backtrace from addr(k,j) for all k, 0≦k<M, and tag each input to identify any stuck-at-Vₖ fault associated with the net, where Vₖ is the state of input addr(k,p), and corresponding faults encountered in backtracing the net are potentially tested by the test; and

Backtrace from write-clock(j) and tag the input to indicate that any stuck-at-0 (write clock stuck “off”) fault associated with the net and corresponding faults encountered while backtracing the net are potentially tested by the test.

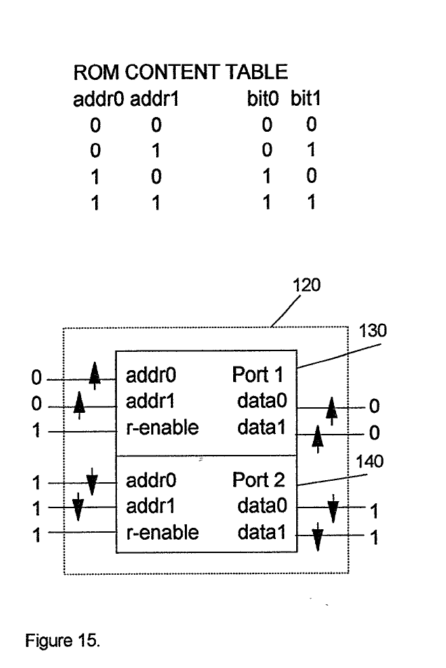

Referring now to FIG. 15, ROM (120) is modeled as a single gate with multiple ports (130 and 140). The ROM is a special case of the RAM previously described in both configuration and behavior, except that a ROM has only read ports. The internal state (i.e., content) of the ROM is defined in a file that is kept with the circuit model and loaded at the same time when the model is brought into main storage at the beginning of the execution of any application program, such as simulation.

When a read-only memory (ROM) is encountered during backtracing, processing must occur for that port whose data output was backtraced into. The notation addr(k,j), read-enable(j), and data-out(i,j) refers to the pins and their associated nets, where i is the data bit position (0≦i<n); j is the port number; k is the address bit position (0≦k<M); n is the number of bits per word; M is the number of address inputs per port; and m=2^{M}, the number of words in the ROM. The backtraced into data output is referred to as data-out (b,p), so that the backtraced into port is port p and the data bit position is b. The value on the data-out(p,b) is represented by V, where V may be either 1, 0, or Z (high impedance).

If read-enable(p) is at 1 (enabling state) and V is different from READOFF (the value on the RAM outputs when disabled), then the read-enable(p) input is backtraced and the read-enable input is tagged to indicate that any stuck-at-0 (stuck-at “disable”) fault associated with the net and corresponding faults encountered in backtracing the net are potentially tested by the test. If read-enable(p) is at 1 (enabling), then the content of the ROM is searched. If ^{˜}V is stored in position b at some address A=(A₀, A₁, . . . A_{M-1}), then each address input addr(j,p) whose value is the complement of Aⱼ is backtraced and the address input is tagged to indicate that any stuck-at Aⱼ fault associated with the net and corresponding faults encountered during backtracing the net are potentially tested by the test. Both the search and the identification of address inputs on which to continue backtracing stop when all the address inputs of port p have been so identified, or when the entire address space has been exhausted, whichever happens first.

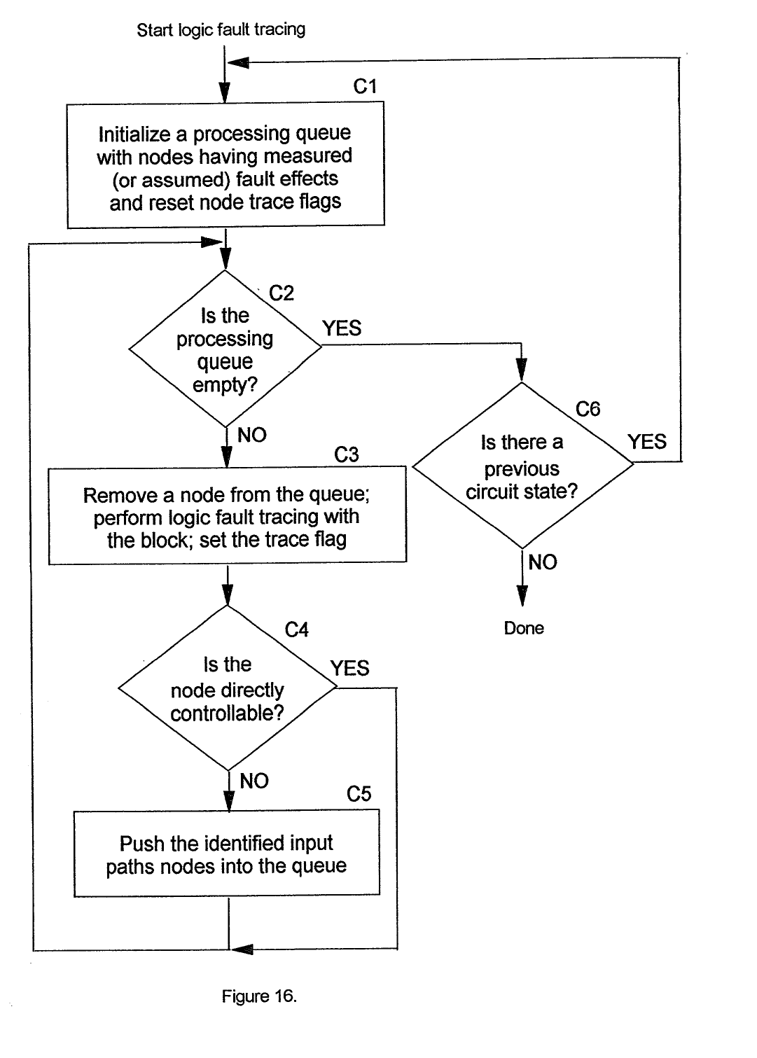

Referring to FIG. 16 showing the steps leading to the logic tracing of the present invention, the process begins with a known circuit state at Step C1. A processing queue, containing all the measured (or assumed) fault effects and associated nodes, is initialized. Step C2 checks for the status of the queue. If the queue no longer holds any nodes to be processed, Step C6 checks for the previous state of the circuit. If there is no previous state of the circuit, the current session of logic fault tracing is complete. If there is a previous circuit state, the trace continues with Step C1 using said previous circuit state. If the queue still holds at least one node to be processed at Step C2, Step C3 fetches the node from the queue and performs logic tracing through the node according to the rules described with reference to FIGS. 7-15 . The result of Step C3 is a subset of the gate faults that is added to the list of faults to be processed by fault simulation and an identification of the block inputs to be further backtraced. Step C4 checks whether or not the processed node is a directly controllable point (either a primary input or a controllable scan latch when a scan load is used). If the decision box returns NO, then the nodes of identified input tracing paths are pushed into the queue at Step C5.

Still referring to FIG. 16, the backtracing process will now be applied to the example shown in FIG. 6. The process starts at step C1 with the good-machine circuit-state GMCS =(in1=1, in2=0, in3=1, in4=1, in5=0, g1=1, g2=0, g3=1, g4=1, g5=0, out1=1, out2=0). This is the result of a fault-free circuit simulation using input pattern (in1=1, in2=0, in3=1, in4=1, in5=0), initializing the processing queue with out 1, and the nodes having measured (or assumed) fault effects 1/0. The decision box at Step C2 yields a NO and out1 is removed from the queue at Step C3. The trace flag is set. Since out1 is not directly controllable, the decision box at Step C4 returns NO. At Step C5, block g4 (which is connected to out1) is identified for further processing and is moved to the processing queue. The process returns now to Step C2. Since the processing queue contains block g4, the decision box returns NO. At Step C3, block g4 is removed from the queue. Its output pin stuck-at-0 fault is identified as the first potential fault, and its trace flag is set. Since block g4 is not directly controllable, the decision box at Step C4 yields NO. At Step C5, blocks g1 and g3 (which drive block g4) are identified for further processing and transferred to the processing queue. The process returns now to Step C2, with the queue containing blocks g1 and g3. The decision box returns NO. At Step C3, block g1 is removed from the queue. Its output pin stuck-at-0 as well as the stuck-at-0 fault on the upper input pin are identified, respectively, as the second and third potential faults, and its trace flag is set. Since block g1 is not directly controllable, the decision box at Step C4 returns a NO. At Step CS, in1 (which is connected to the upper input pin of block g1) is identified for further processing and moved to the processing queue. The process return to Step C2, with the queue having blocks g3 and in1. The decision box returns NO. Block g3 is removed from the queue at Step C3. Its output stuck-at-0 fault is identified as the fourth potential fault, and its trace flag is set. Since block g3 is not directly controllable, the decision box returns NO. At Step C5, in3 (which is connected to the lower input of block g3) is identified for further processing and moved to the processing queue Block g1 (which is connected to the upper input of block g3) is not added to the queue since its trace flag was already set. Now the process stands at Step C2 with the processing queue containing in1 and in3. The decision box at Step C2 returns NO and in1 is removed from the queue at Step C3. Its stuck-at-0 fault is identified as the fifth potential fault, and its trace flag is set. Since in1 is a primary input and, hence, directly controllable, the decision box at Step C4 yields YES. The process returns now to Step C2 once again, with the processing queue containing in3. In3 is eliminated from the processing queue at Step C3, its stuck-at-0 fault is identified as the sixth potential fault, and its trace flag is set. Since in3 is directly controllable, the decision box at Step C4 returns YES, and the process returns to Step C2. At this point, the processing queue contains no other blocks. The decision box at Step C2 returns YES and, subsequently, the decision box at Step C6 yields NO, indicating that the backtracing session is terminated. In total, six potentially tested faults were identified for processing by fault simulation.

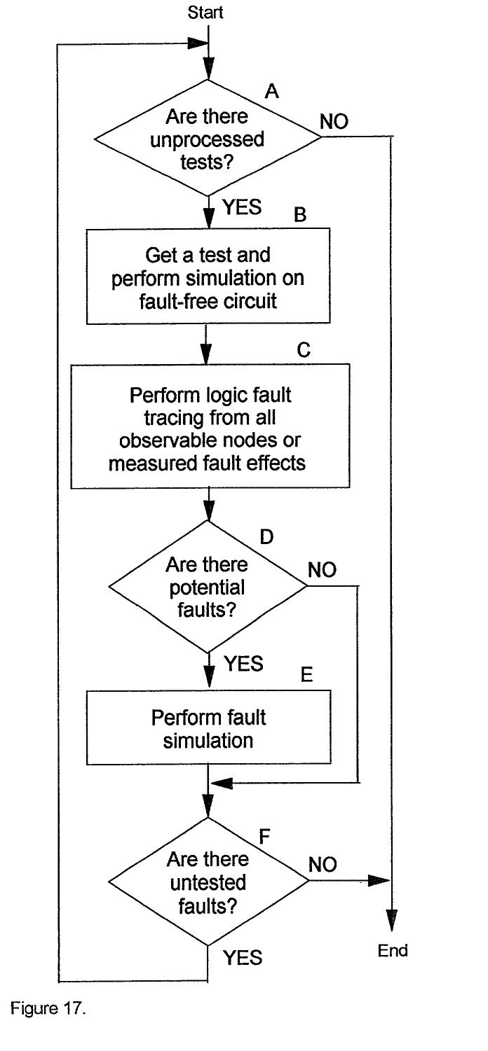

FIG. 17 shows the flow of a typical fault simulation process incorporating the present invention of logic fault tracing. When there are unprocessed tests, the decision box at Step A leads to fault-free circuit simulation using any suitable prior-art method at Step B. Step C performs logic tracing based on the fault-free circuit simulation, as outlined in FIG. 16. Step D checks whether there are identified potential faults to be processed by simulation of faulty-circuits at Step E. Step F checks whether or not there remain any untested faults. The fault simulation process terminates when there are no more tests to be simulated or all faults are tested.

The present invention can easily be integrated into an existing simulation environment that processes designs without memory elements. Once the good-machine simulation of a test is performed the backtracing procedure as outlined in FIG. 16 is executed. This is represented by Step C (see FIG. 17). A typical combinational test contains the following patterns which are applied in the order as they appear:

A Test for a Combinatorial Circuit

Pattern A: Set primary inputs

(resulting in a good-machine circuit state, GMCS)

Pattern B: Observe primary outputs

A good-machine circuit state (GMCS) results immediately after Pattern A is simulated. The backtracing procedure of FIG. 16 begins at each failing output (when used with diagnostic simulation) or from each primary output. Then the backtracing continues block-by-block towards the primary inputs using the GMCS, and following the rules which govern the backtracing through individual blocks, as illustrated in FIGS. 7-15. The resulting list of potential faults for the test is then processed by prior-art fault simulation methods.

With full-scan, partial-scan and non-scan designs, the present invention can also be integrated into an existing fault simulation environment by performing all good-machine simulation of a test first and keeping track of the resulting good-machine circuit states.

A typical fill-scan based test includes the following patterns which are applied in the order as they appear:

A Test for a Full-Scan Circuit

Pattern A: Scan-load (or shift-in)

Pattern B: Set primary non-clock inputs

(resulting the first good-machine circuit state, GMCS-1)

Pattern C: Observe primary outputs

Pattern D: Pulse a clock

(resulting the second good-machine circuit state, GMCS-2)

Pattern E: Observe primary outputs

Pattern F: Scan-unload (or shift-out)

A typical prior-art fault simulation process simulates Pattern A and Pattern B to create a first good-machine circuit state, GMCS-1. Next, it performs fault simulation with the untested faults based on GMCS-1. Then, Pattern D is simulated, propagating the good-machine values as well as fault effects from the inputs of memory elements to their outputs (in case of complex RAMs, additional clocks may be used to facilitate the write-read operations). The second good-machine circuit state, GMCS-2, is then generated by forward propagating the newly updated values of the memory elements. After GMCS-2 is derived, fault simulation is performed based on GMCS-2. It is worth noting that the process does not need saving GMCS-1 after simulating Pattern D and beyond. Thus, it is possible to clear GMCS-1 after completing the fault simulation with GMCS-1 and before simulating Pattern D, although this is a only a matter of implementation.

In order to use the present invention with full-scan designs, a different fault simulation flow must be used. Taking the same full-scan test as an example, the present invention requires deriving GMCS-1 and GMCS-2 first, and saving GMCS-1 in some form for later retrieval. This requires first a good-machine simulation of the entire test. The backtracing procedure of FIG. 16 starts with GMCS-2 at the primary outputs and observable nodes with observable fault effects (or failure data if it is in a diagnostic fault simulation environment), similar to the combinational circuit example. Once backtracing is completed with GMCS-2, the identified fault effects at the outputs of memory elements which are controlled by Pattern D are moved to the inputs of these memory elements, in accordance with the rules established earlier by the present invention, specifically, with reference to FIGS. 9, 14 and 15. GMCS-2 is saved in some form, and GMCS-1 is restored. The backtracing procedure is continued on GMCS-1 with the fault effects at the inputs of memory elements. The resulting list of potentially tested faults is then processed by fault simulation which simulates the faults with GMCS-1 first and then, with GMCS-2 next, in order to identify the tested faults. (Note: the present invention requires that all good-machine circuit states be known before the backtracing procedure is applied. However, it does not require changes to existing fault simulation, other than a simple rearrangement of the order of the processing steps).

With partial-scan and non-scan designs, the typical test sets contain a significant number of sequential tests, having the same clocks being pulsed more than once before fault effects are captured and/or observed at either the primary output pins, or measure latches, or both. Typical partial-scan and non-scan tests are shown below:

A Test for a Partial-Scan Circuit

Pattern A.1: Scan-load (or shift-in)

Pattern B.1: Set primary non-clock inputs

(resulting the first good-machine circuit state, GMCS-1)

Pattern D.1: Pulse a clock

(resulting the second good-machine circuit state, GMCS-2)

Pattern A.2: Scan-load (or shift-in)

Pattern B.2: Set primary non-clock inputs

(resulting the third good-machine circuit state, GMCS-3)

Pattern D.2: Pulse a clock

(resulting the fourth good-machine circuit state, GMCS-4)

Pattern E.2: Observe primary outputs

Pattern F.2: Scan-unload (or shift-out)

A Test for a Non-Scan Sequential Circuit

Pattern B.1: Set primary non-clock inputs

(resulting the first good-machine circuit state, GMCS-1)

Pattern D.1: Pulse a clock

(resulting the second good-machine circuit state, GMCS-2)

Pattern B.2: Set primary non-clock inputs

(resulting the third good-machine circuit state, (GMCS-3)

Pattern D.2: Pulse a clock

(resulting the fourth good-machine circuit state, (GMCS-4)

Pattern E.2: Observe primary outputs

In cases of partial scan and non-scan tests, the backtracing procedure of the present invention processes the good-machine circuit states in the following order: GMCS-4, GMCS-3, GMCS-2, and GMCS-1, and in a similar way as with the full-scan test example described above. While processing one GMCS, the remaining GMCSs are saved. GMCS is deleted after completing the fault simulation with GMCS. It is important to note that different fault simulation implementations and fault models may have different definitions of a good-machine circuit state than what has been illustrated in the above examples. The principles of the backtracing procedure as shown in FIG. 16 are still applicable.

The present invention can be realized in hardware, software, or a combination of hardware and software. It may also be implemented in a centralized fashion in one computer system, or in a distributed fashion where different elements are spread across several interconnected computer systems. Any computer system—or other apparatus adapted for carrying out the methods described herein—is suitable. A typical combination of hardware and software could be a general purpose computer system with a computer program that, when being loaded and executed, controls the computer system such that it carries out the methods described herein. The present invention can also be embedded in a computer program product, which comprises all the features enabling the implementation of the methods described herein, and which—when loaded in a computer system —is able to carry out these methods.

Computer program means or computer program in the present context mean any expression, in any language, code or notation, of a set of instructions intended to cause a system having an information processing capability to perform a particular function either directly or after conversion to another language, code or notation and/or reproduction in a different material form.

Whereas the present invention has been described by way of the foregoing embodiment, it is needless to say that various changes and modifications can be made, e.g., in the steps described in the flow charts summarizing the main features of the invention or in the topology of the logic circuit without departing from the scope and the spirit of the subject matter of the present invention.

What is claimed is:

1. In an integrated circuit (IC) having at least one fault to be tested by fault simulation using at least one test, each of said tests including at least one input test vector, a method for improving the efficiency of the fault simulation comprising the steps of:
a) performing a good machine simulation on said IC with said at least one test to obtain values of each internal node of said IC;
b) based on said good machine simulation, identifying faults in said IC that are potentially tested by said at least one test;
c) with said at least one test, performing a fault simulation on said faults that were identified as potentially tested; and
d) repeating steps a) through c) for each of said at least one test

2. The method as recited in of claim 1, wherein step b) further comprises backtracing from each observable node, said backtrace through each of said internal nodes being based on said fault-free circuit simulation and being limited to paths along which a faulty value has a possibility of propagating to said observable node.

3. The method as recited in claim 1, wherein said tests are generated by a test generator.

4. The method as recited in claim 1, wherein said fault-free-circuit simulation is performed by a logic simulator.

5. The method as recited in claim 1, wherein said fault simulation is performed by a hardware fault simulator.

6. The method as recited in claim 2, wherein the observed results of said test further limit the number of faults requiring processing by said fault simulation by starting said backtraces from only observable nodes wherein a fault was detected.

7. The method as recited in claim 1, wherein said IC comprises memory elements that are selected from the group that includes latches, flip-flops, random-access-memories (RAMs), and read-only-memories (ROMs) embedded in said IC.

8. In an integrated circuit (IC) having at least one fault to be tested by fault simulation using at least one test, each of said tests including at least one input test vector, a method for improving the efficiency of the fault simulation comprising the steps of:
a) performing a good machine simulation on said IC with said at least one test to obtain values of each internal node of said IC;
b) based on said good machine simulation, identifying faults in said IC that are blocked by said at least one test from being observed at an observable point of said IC;
c) with said at least one test, performing a fault simulation on said faults that were identified as not being blocked; and
d) repeating steps a) through c) for each of said at least one test.

9. A program storage device readable by machine, tangibly embodying a program of instructions executable by the machine to perform a method for improving the efficiency of a fault simulation of an integrated circuit (IC) having at least one fault to be tested by the fault simulation using at least one test, each of said tests including at least one input test vector, said method steps comprising:
a) performing a good machine simulation on said IC with said at least one test to obtain values of each internal node of said IC;
b) based on said good machine simulation, identifying faults in said IC that are blocked by said at least one test from being observed at an observable point of said IC;
c) with said at least one test, performing a fault simulation on said faults that were identified as not being blocked; and
d) repeating steps a) through c) for each of said at least one test

10. A computer program product comprising:
a computer usable medium having computer readable program code means embodied therein for improving the efficiency of a fault simulation of an integrated circuit (IC) having at least one fault to be tested by said fault simulation using at least one test, each of said tests including at least one input test vector, the computer readable program code means in said computer program product comprising:
a) computer readable program code means for causing a computer to perform good machine simulation on said IC with said at least one test to obtain values of each internal node of said IC
b) computer readable program code means for causing the computer to identify faults in said IC that are blocked by said at least one test from being observed at an observable point of said IC, based on said good machine simulation;
c) computer readable program code means for causing the computer to perform a fault simulation on said faults that were identified as not being blocked with said at least one test; and
d) computer readable program code means for causing the computer to repeat steps a) through c) for each of said at least one test.
